(19) United States
(12) Patent Application Publication
(10) Pub. No.: US 2023/0369190 A1
(43) Pub. Date: Nov. 16, 2023

(54) INTEGRATION PACKAGE WITH INSULATING BOARDS

(71) Applicant: WALTON ADVANCED ENGINEERING INC., Kaohsiung (TW)

(72) Inventors: CHUN JUNG LIN, Kaohsiung (TW); RUEI TING GU, Kaohsiung (TW)

(73) Assignee: WALTON ADVANCED ENGINEERING INC., Kaohsiung (TW)

(21) Appl. No.: 17/893,341

(22) Filed: Aug. 23, 2022

(30) Foreign Application Priority Data
May 11, 2022 (TW) 111117656

(51) Int. Cl. H01L 23/498

(52) U.S. Cl. CPC H01L 23/49833; H01L 23/49816; H01L 23/49838; H01L 23/49866

(57) ABSTRACT

The present application discloses an integration package with insulating boards, which features an insulating board structure replacing a plurality of printed circuit boards and packaging materials in a conventional POP structure and comprises a base substrate, a basic circuit and at least an electronic component: the basic circuit is exposed on an upper surface of the base substrate; the electronic component and the basic circuit are electrically connected with each other; both the base substrate and the electronic component are thermally compressed and covered by a first insulating board.

### BACKGROUND OF THE INVENTION

### Field of the Invention

The present invention relates to a Package-on-Package (POP) structure, particularly an insulating board structure replacing a plurality of printed electric circuits in a conventional POP structure and substituting a package material structure.

### Description of the Prior Art

Because input/output terminals are designed on a chip as an upstream component in a sophisticated electronic product, the issue to introduce more contacts into limited space of a semiconductor package matching the chip is a challenge to popular Package-on-Package (POP) applications, that is, more I/O contacts should be arranged in less space.

In general, an IC chip in the modern integrated-circuit package technology is encapsulated in package materials first and supplemented by an electric circuit on a substrate for creation of additional space in which more I/O contacts are added.

There have been several patents with respect to a POP structure published as follows:

WO2017111789A1 discloses a Package-on-Package (POP) device based on an Embedded Wafer-Level Ball Grid Array (Ewlb) or an Embedded Panel-Level Ball Grid Array (ePLB) and a method for development of the POP device. According to one embodiment in WO2017111789A1, the POP device comprises a chip embedded into a module layer and a substrate directly contacting with a surface of the module layer. As shown in WO2017111789A1, a via designed in one embodiment penetrates the module layer for electric connection to a contact element on a surface of the substrate contacting with the module layer. For development of the POP device, a molding material is poured over a chip mounted on a module carrier in one embodiment; then, a base material is compressed into the molding material. After the molding material cured, a module layer in which a chip is encapsulated forms and adheres to the base material.

TW I754839 discloses an interposer for development of a reinforcing structure which is designed in a kernel layer of the interposer. The interposer links a packaging device through a conductive connector. The reinforcing structure contributes to the packaging device with rigidity and heat dissipation. In some embodiments, the interposer is characteristic of a hole punched in the upper kernel layer and linking a concaving bonding pad. In some embodiments, connectors are installed between the interposer and a packaging device and metal posts linking the packaging device are surrounded with soft soldering materials which are connected with the interposer.

TW I628742 discloses a Package-on-Package (POP) structure which comprises a first tabular structure and a second tabular structure. The first tabular structure has a first plane and a second plane, both of which are opposite to each other. The first tabular structure comprises a first dielectric layer and a first electronic component. The first electronic component installed inside the first dielectric layer has a first active surface which constitutes one portion of the second plane. The second tabular structure has a third plane and a fourth plane, both of which are opposite to each other. The third plane faces the second plane and is fixed on the second surface. The second tabular structure comprises a second dielectric layer and at least a second electronic component. The second electronic component installed inside the second dielectric layer has a second active surface which constitutes one portion of the third plane.

However, the issues of the thickness of a package and temperature of a running product have drawn more and more attention when the number of layers in a POP structure as well as functionality is complicated because of evolution of the advanced encapsulation process over time. Moreover, the frequent replacement cycle of electronic devices imposes huge pressure on the whole cost control of a manufacturer.

### SUMMARY OF THE INVENTION

In virtue of the above issue, an integration package with insulating boards provided in the present disclosure relies on an insulating board structure replacing a plurality of printed circuit boards in a conventional POP structure for cost reduction in contrast to a POP structure.

Accordingly, the present disclosure is to provide an integration package with insulating boards through which a base substrate and electronic components are thermally compressed and covered by an insulating board structure for completion of a package.

The present disclosure is also to provide an integration package with insulating boards which replace printed circuit boards and a package structure for a slim overall thickness of a package.

The present disclosure is also to provide an integration package with insulating boards in which an insulating board is provided with a default electric circuit as a conductive electric circuit for electrical conduction of different layers.

The present disclosure is also to provide an integration package with insulating boards in which a copper layer is additionally covered on an insulating board structure for prevention of electromagnetic interferences efficiently.

The present disclosure is also to provide an integration package with insulating boards in which a copper layer is additionally covered on an insulating board structure for passive discharge of waste heat from a POP structure.

To this end, the major technical measures in the present application are embodied according to the following technical solution. An integration package with insulating boards in the present disclosure comprises a base substrate, a basic circuit and at least an electronic component: the basic circuit is exposed on an upper surface of the base substrate; the electronic component and the basic circuit are electrically connected with each other; the base substrate and the electronic component are thermally compressed and covered by a first insulating board.

The purposes and technical issues in the present disclosure are further embodied by referring to the following technical measures.

In the integration package, the first insulating board comprises a first electric circuit designed on the upper surface and electrically connected with another electronic component.

In the integration package, the base substrate is provided with a plurality of data pins and at least a grounding pin on a lower surface.

In the integration package, the electronic component can be an active component, a passive component or a memory.

In the integration package, the first insulating board has a first copper layer on the surface.

In the integration package, the first insulating board is penetrated by a first lower conductive via in which a first conducting material is filled for electrical conduction through the basic circuit and the first lower conductive via.

In the integration package, the first electric circuit and the electronic component are thermally compressed and covered by a second insulating board.

In the integration package, the second insulating board comprises a second electric circuit designed on the upper surface and electrically connected with another electronic component.

In the integration package, the second insulating board has a second copper layer on the surface.

In the integration package, the second insulating board is penetrated by a second lower conductive via in which a second conducting material is filled for electrical conduction through the first electric circuit and the second lower conductive via.

In contrast to the prior art, an integration package with insulating boards proves effective in: (1) a base substrate and other components are thermally compressed and covered by an insulating board structure for the function of a package; (2) an insulating board structure replacing printed circuit boards and a conventional package structure contributes to setup cost reduction and an overall thickness; (3) an insulating board structure covered by an additional copper layer reduces overall temperature and further prevents electromagnetic interferences.

### BRIEF DESCRIPTIONS OF THE DRAWINGS

FIG. 1a is a schematic view of a first integration package in the first embodiment.

FIG. 1b is a schematic view of a second integration package in the first embodiment.

FIG. 2 is a schematic view of an integration package in the second embodiment.

FIG. 3a is a schematic view of a first integration package in the third embodiment.

FIG. 3b is a schematic view of a second integration package in the third embodiment.

FIG. 3c is a schematic view of a third integration package in the third embodiment.

FIG. 3d is a schematic view of a fourth integration package in the third embodiment.

FIG. 4 is a schematic view of an integration package in the fourth embodiment.

### DETAILED DESCRIPTIONS OF THE PREFERRED EMBODIMENTS

An integration package with insulating boards is explained in the preferred embodiments for clear understanding of purposes, characteristics and effects of the present application.

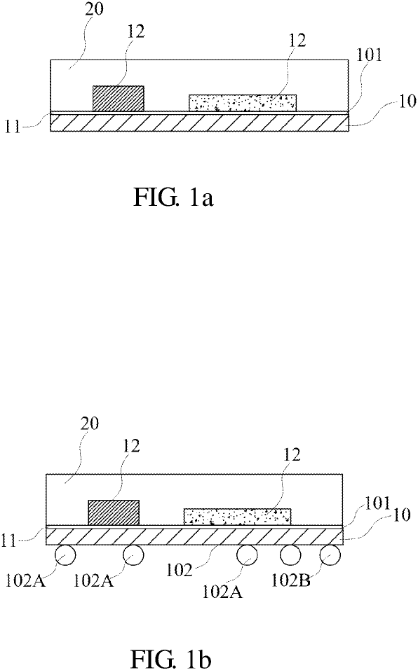

FIGS. 1a and 1b illustrate an integration package with insulating boards in the first embodiment. Referring to FIG. 1a which illustrates an integration package with insulating boards comprises a base substrate (10), a basic circuit (11) and at least an electronic component (12): the basic circuit (11) is exposed on an upper surface (101) of the base substrate (10); the electronic component (12) and the basic circuit (11) are electrically connected with each other; both the base substrate (10) and the electronic component (12) are thermally compressed and covered by a first insulating board (20).

Specifically, the base substrate (10) is usually a circuit board, for example, a printed circuit board with single-layered or multiple-layered circuits, a lead frame, a polyimide circuit board, a BT-based PCB or a chip-on-board; the base substrate (10) comprises a basic circuit (11), as an interface for electrical conduction, forming inside and exposed on the upper surface (101) of the base substrate (10). In the present disclosure, the electronic component (12) can be an active component, a passive component or a memory and the electronic component (12) and the basic circuit (11) are electrically connected with each other.

Furthermore, the first insulating board (20), which is an insulating sheet made of woven glass as well as epoxy resins, will be softened after heating such that both the base substrate (10) and the electronic component (12) are thermally compressed and covered by the first insulating board (20) and protected by the cooled and re-cured first insulating board (20).

For convenience of a following working process, the base substrate (10) comprises a plurality of data pins (102A) and at least a grounding pin (102B) on a lower surface (102), as shown in FIG. 1b. The data pins (102A) are effective in providing electrical connections from different electronic components to outside; the grounding pin (102B), which is the ground connection as a potential reference point for design of an electric circuit universally, provides a reference potential for a whole electric circuit, that is, 0V at the grounding pin for a unified electrical potential of a whole electric circuit.

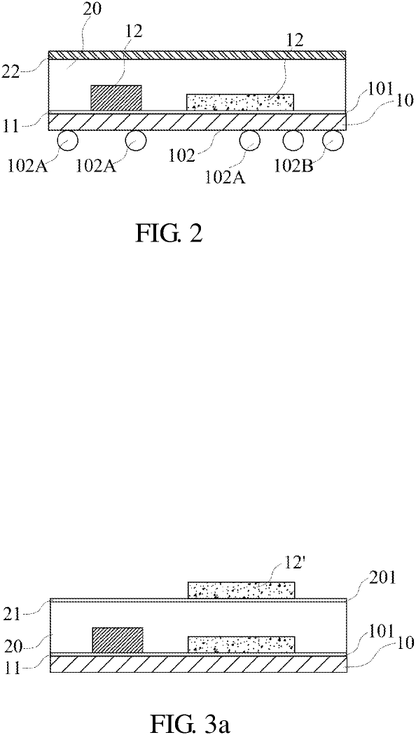

Referring to FIG. 2 which illustrates an integration package with insulating boards in the second embodiment. In the second embodiment, the first insulating board (20) is provided with a first copper layer (22) on the surface that is different from the design in the first embodiment.

Practically, the first copper layer (22), which is metal surface coating on the first insulating board (20), prevents electromagnetic interferences between outside and upper/lower layers, discharging waste heat and reducing temperature of electronic components inside a package.

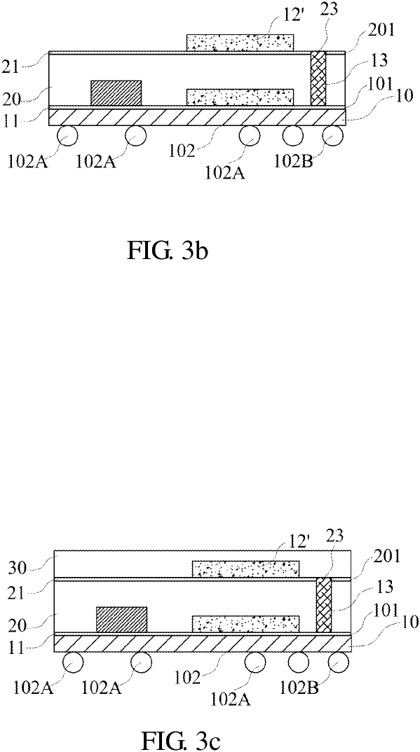

Referring to FIGS. 3a, 3b and 3c which illustrate an integration package with insulating boards in the third embodiment. In the third embodiment, the first insulating board (20) is provided with a first electric circuit (21) designed on the upper surface (201) and electrically connected with another electronic component (12′) that is different from the first embodiment.

In detail, the first insulating board (20), which is an insulating sheet made of woven glass as well as epoxy resins, will be softened after heating such that both the base circuit (11) and the electronic component (12) are thermally compressed and covered by the first insulating board (20) and protected by the cooled and re-cured first insulating board (20); the first insulating board (20) is a printed circuit board with single-layered (as shown in FIG. 3a) or multiple-layered circuits such that the first electric circuit (21) forming inside the first insulating board (20) is exposed on the upper surface (201) of the first insulating board (20) and taken as an interface for electrical conduction. In the present disclosure, the electronic component (12′) can be an active component, a passive component or a memory and the electronic component (12′) and the first electric circuit (21) are electrically connected with each other.

Furthermore, for electrical conduction between the basic circuit (11) and the first electric circuit (21) or between electronic components (12, 12′), the first insulating board (20) should be penetrated by a first lower conductive via (23) in which a first conducting material (13) is filled for electrical conduction through the basic circuit (11) and the first conducting material (13).

Practically, the first lower conductive via (23), as shown in FIG. 3b, penetrates the first insulating board (20) from the first electric circuit (21) such that the basic circuit (11) is exposed to outside; in the present disclosure, the first conducting material (13) is a conductive gluey substance which will cure after quantitative change for object fixing and electrical conduction.

Preferably, as shown in FIG. 3c, both the first electric circuit (21) and the electronic component (12′) are thermally compressed and covered by a second insulating board (30).

In the present disclosure, the second insulating board (30), which is an insulating sheet made of woven glass as well as epoxy resins, will be softened after heating such that both the first electric circuit (21) and the electronic component (12′) are thermally compressed and covered by the second insulating board (30) and protected by the cooled and re-cured second insulating board (30).

Furthermore, as shown in FIG. 3d, the second insulating board (30) is provided with a second copper layer (32) on the surface.

Specifically, the second copper layer (32), which is metal surface coating on the second insulating board (30), prevents electromagnetic interferences between outside and upper/lower layers, discharging waste heat and reducing temperature of electronic components inside a package.

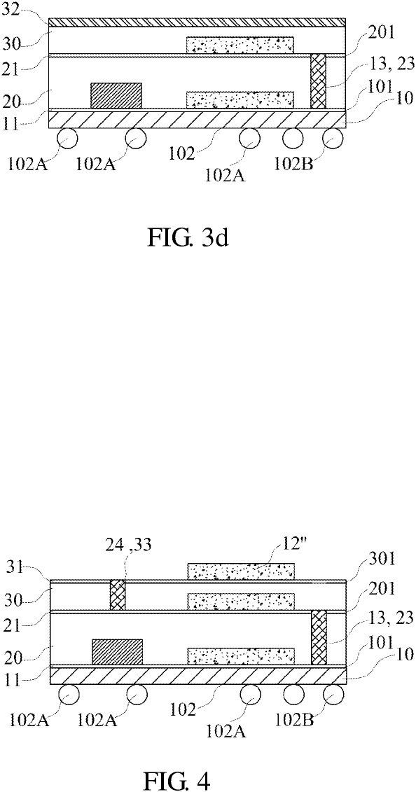

Referring to FIG. 4 which illustrates an integration package with insulating boards in the fourth embodiment. In the fourth embodiment, the second insulating board (30) is provided with a second electric circuit (31) designed on the upper surface (301) and electrically connected with another electronic component (12″) that is different from the third embodiment.

In general, the second insulating board (30), which is an insulating sheet made of woven glass as well as epoxy resins, will be softened after heating such that both the second electric circuit (31) and the electronic component (12″) are thermally compressed and covered by the second insulating board (30) and protected by the cooled and re-cured second insulating board (30). The first insulating board (20) is a printed circuit board with single-layered (as shown in FIG. 3a) or multiple-layered circuits; the second electric circuit (31) forming inside the second insulating board (30) is exposed on the upper surface (301) of the second insulating board (30) and taken as an interface for electrical conduction. In the present disclosure, the electronic component (12″) can be an active component, a passive component or a memory and the electronic component (12″) and the second electric circuit (31) are electrically connected with each other.

Furthermore, for electrical conduction among the basic circuit (11), the first electric circuit (21) and the second electric circuit (31) or among electronic components (12, 12′, 12″), the second insulating board (30) should be penetrated by a second lower conductive via (33) in which a second conducting material (24) is filled for electrical conduction through the first electric circuit (21) and the second conducting material (24).

Practically, the second lower conductive via (33), as shown in FIG. 4, penetrates the second insulating board (30) from the second electric circuit (31) such that the first electric circuit (21) is exposed to outside; in the present disclosure, the second conducting material (24) is a conductive gluey substance which will cure after quantitative change for object fixing and electrical conduction.

Accordingly, an integration package with insulating boards which is different from other semiconductor packaging structures and referred to as creative work in applications of semiconductor package-on-package meets patentability and is applied for the patent.

It should be reiterated that the above descriptions present the preferred embodiments of an integration package with insulating boards and any equivalent changes or modifications in specifications, claims or drawings still belong to the technical field within the present disclosure with reference to claims hereinafter.

What is claimed is:

1. An integration package with insulating boards, comprising: a base substrate, a basic circuit and at least an electronic component wherein the basic circuit is exposed on an upper surface of the base substrate, the electronic component and the basic circuit are electrically connected with each other, and both the base substrate and the electronic component are thermally compressed and covered by a first insulating board.

2. The integration package as claimed in claim 1 wherein the first insulating board comprises a first electric circuit on the upper surface and the first electric circuit is electrically connected with another electronic component.

3. The integration package as claimed in claim 1 wherein the base substrate is provided with a plurality of data pins and at least a grounding pin on a lower surface.

4. The integration package as claimed in claim 1 wherein the electronic component can be an active component, a passive component or a memory.

5. The integration package as claimed in claim 1 wherein the first insulating board has a first copper layer on the surface.

6. The integration package as claimed in claim 2 wherein the first insulating board is penetrated by a first lower conductive via in which a first conducting material is filled for electrical conduction through the basic circuit and the first lower conductive via.

7. The integration package as claimed in claim 6 wherein the first electric circuit and the electronic component are thermally compressed and covered by a second insulating board.

8. The integration package as claimed in claim 7 wherein the second insulating board comprises a second electric circuit on the upper surface and the second electric circuit is electrically connected with another electronic component.

9. The integration package as claimed in claim 7 wherein the second insulating board has a second copper layer on the surface.

10. The integration package as claimed in claim 8 wherein the second insulating board is penetrated by a second lower conductive via in which a second conducting material is filled for electrical conduction through the first electric circuit and the second lower conductive.
